(19) United States
(12) Patent Application Publication
(10) Pub. No.: US 2015/0319390 A1
(43) Pub. Date: Nov. 5, 2015

(54) STACKED AND TILED FOCAL PLANE ARRAY

(71) Applicant: Sandia Corporation, Albuquerque, NM (US)

(72) Inventors: Reno Lee Sanchez, Albuquerque, NM (US); Nicolas Bikhazi, Albuquerque, NM (US); Jeffrey L. Rienstra, Albuquerque, NM (US); Randolph R. Kay, Albuquerque, NM (US); Michael L. Holmes, Albuquerque, NM (US)

(21) Appl. No.: 14/589,300

(22) Filed: Jan. 5, 2015

Related U.S. Application Data
(60) Provisional application No. 61/986,406, filed on Apr. 30, 2014.

(51) Int. Cl. H04N 5/378; H01L 27/146

(52) U.S. Cl. CPC H04N 5/378; H01L 27/14643

(57) ABSTRACT

Technologies pertaining to focal plane arrays (FPAs) are disclosed herein. In a general embodiment, the FPA includes a detector layer and a stack of discrete processing layers, where the stack of discrete processing layers is hybridized with the detector layer. The processing layers are each configured to perform a respective function. At least one processing layer includes multiple identical tiles, where each tile is configured to perform an identical function.

### RELATED APPLICATION

This application claims priority to U.S. Provisional Patent Application No. 61/986,406, filed on Apr. 30, 2014, and entitled “PLATFORM FOCAL PLANE ARRAY”, the entirety of which is incorporated herein by reference.

### STATEMENT OF GOVERNMENTAL INTEREST

This invention was developed under Contract DE-AC04-94AL85000 between Sandia Corporation and the U.S. Department of Energy. The U.S. Government has certain rights in this invention.

### BACKGROUND

Conventional focal plane arrays (FPAs) (also sometimes referred to as staring arrays) are made up of two main components: 1) a detector array; and 2) a read-out integrated circuit (ROIC). The ROIC is a circuit that is configured to capture and process the data that is indicative of photos captured by the detector array and converted into electric current or voltage (at various spatially distributed locations of the detector), where the electric current or voltage is a function of incident electromagnetic energy across the detector. The ROIC is then configured to transmit the data to external electronics.

Conventionally, FPAs are quite costly to develop, with costs that can reach into tens of millions of dollars. The costliness of development of FPAs is due to several reasons: 1) each FPA is designed from scratch and customized for a particular mission; 2) yield of manufacturing an FPA that meets requisite operational standards (e.g., 99% operational) is low. As FPAs become larger, the yield can be expected to be further reduced.

### SUMMARY

Technologies pertaining to development and manufacture of a focal plane array (FPA) are disclosed herein. More specifically, the present disclosure is directed to various technologies pertaining to developing an FPA based upon three-dimensional stacking technologies, where discrete processing layers are stacked, one on top of another, such that adjacent processing layers are mechanically and communicatively bonded. The discrete processing layers can be manufactured and tested separately from one another, and mechanically and electrically (or optically) coupled once processing layers that meet operational standards have been identified.

In a general embodiment, as the FPA comprises a plurality of discrete processing layers, one or more of such layers may be used for multiple missions, thereby reducing overall development cost. For example, a first FPA can be developed that comprises a first processing layer, a second processing layer, and a third processing layer. Subsequently, a second FPA may be developed that includes a first processing layer, wherein the first processing layer of the second FPA may have functionality that is equivalent to the functionality of the first processing layer of the first (previously developed) FPA. The first processing layer of the first FPA, then, can be used in the second FPA, thereby avoiding development costs associated with designing circuitry from scratch. Therefore, it is possible to develop a new FPA, customized for a particular mission, by using previously developed processing layers existent in a library.

In another embodiment, a discrete processing layer of an FPA can comprise a plurality of identical tiles, each of which is configured to perform an identical function with respect received signals. Further, a tile can comprise multiple identical sub-tiles, each of which is configured to perform an identical function with respect to received signals. Since size of sub-tiles may be relatively small, yield is expected to rise, as an imperfection on one portion of a wafer that includes a first sub-tile will not impact a second sub-tile on a second portion of the wafer. Sub-tiles can be diced from the wafer, and those identified as meeting operational standards can be retained and planarly arranged with other sub-tiles that meet the operational standards to form tiles. The tiles can be tested, and those meeting the operational standards can be planarly arranged with other tiles that meet the operational standards to form a processing layer. The processing layer may then be mechanically and communicatively (electrically or optically) bonded with at least one other discrete processing layer to form a tiled stack of processing layers.

Additional features and advantages are described herein, and will be apparent from the following Detailed Description and the figures.

### BRIEF DESCRIPTION OF THE DRAWINGS

FIG. 1 is a cross-sectional view of an exemplary focal plane array (FPA).

FIG. 2 is another cross sectional diagram of an exemplary FPA.

FIG. 3 is yet another cross-sectional view of an exemplary FPA.

FIG. 4 is an isometric view of an exemplary FPA.

FIG. 5 illustrates a processing layer of an FPA that comprises a plurality of identical tiles, where each tile comprises a plurality of identical sub-tiles.

FIG. 6 is a flow diagram illustrating an exemplary methodology for forming an FPA.

FIG. 7 is a flow diagram illustrating an exemplary methodology for forming a discrete processing layer to be included in an FPA.

### DETAILED DESCRIPTION

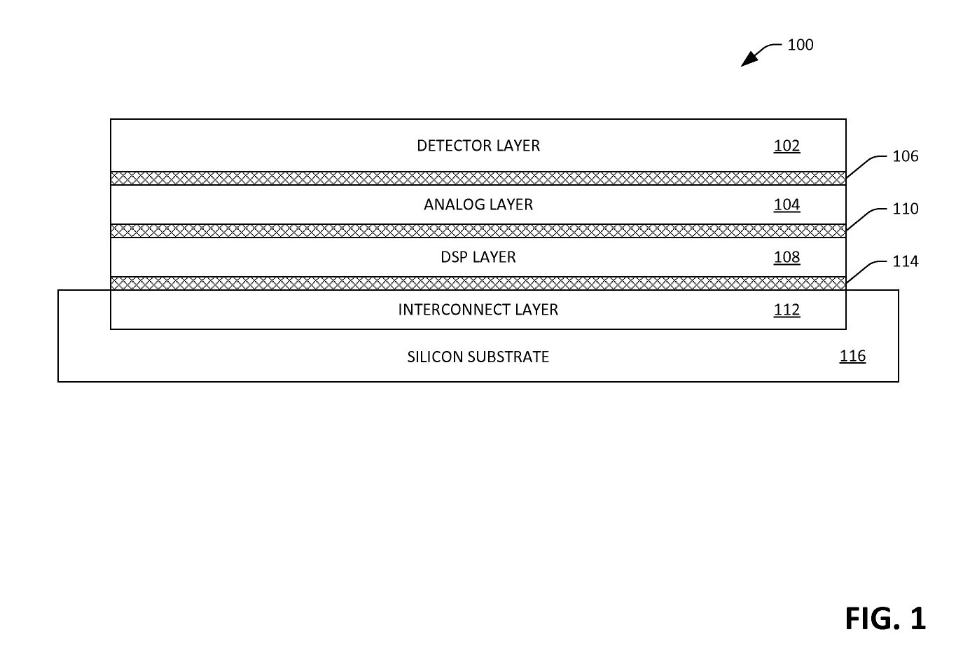

The present disclosure is directed to technologies pertaining to focal plane arrays (FPAs). With reference now to FIG. 1, in a general embodiment, a cross-sectional view of an FPA is illustrated. Generally, the FPA 100 comprises a plurality of discrete layers, wherein the layers are stacked one on top of another and mechanically and electrically (or optically) coupled to one another. The stacking of the plurality of layers allows for different processing functions to be placed in different, discrete layers. When designing an FPA for a particular mission, layers can be added, subtracted, or modified (e.g., from an existing design or from a library of layer designs) in order to meet needs of the mission. In the FPA 100, each processing function can be based upon the same or different lithography nodes, depending upon what is best for each processing function (e.g., density versus cost). This allows for each function to be optimized at each layer. Further, the designer of the FPA can mix and match state-of-the-art (SOA) functions designed by different vendors to create the FPA such that capabilities of the FPA exceed those of conventional FPAs. Furthermore, one or more layers can be modified (either to meet a new mission or to take advantage of technology advances), while keeping all other layers the same. Layers can also be added to meet a new mission requirement. This allows to create a customized solution for a particular mission, at much less development cost. Moreover, layers can be removed if a specific mission does not need the functionality provided by the layers, thereby reducing overall system cost.

As mentioned previously, the FPA 100 comprises a plurality of stacked layers. The stacked layers include a detector layer 102 that is formed of a photodiode material. Exemplary photodiode materials that can be used to form the detector layer 102 include, but are not limited to, silicon, mercury cadmium telluride (HgCdTe), indium antimonide (InSb), indium gallium arsenide (InGaAs), vanadium oxide (VOx), amongst others. Accordingly, the detector layer 102 can be configured to detect radiation in the visible spectrum, the near-infrared spectrum, the infrared spectrum, ultraviolet spectrum, etc. In an exemplary embodiment, the detector layer 102 can be formed of a single piece of photodiode material. In another example, the detector layer 102 may be formed of an array of detectors.

The FPA 100 also includes, in an example, a discrete analog layer 104, which is mechanically and electrically coupled to the detector layer 102. The analog layer 104 can include analog circuitry that is configured to receive an electric signal from the detector layer 102 and process such electric signal to generate a processed signal. In an exemplary embodiment, the analog layer 104 can comprise analog circuitry that is configured to perform preconditioning functions over signals received from the detector layer 102 and/or analog to digital (A/D) conversion. Thus, the analog circuitry can include an analog to digital (A/D) converter, such that the processed signal output by the analog layer 104 is a digital signal. Further, exemplary preconditioning functions can include analog filtering, noise reduction, etc. The analog layer 104 is electrically coupled to the detector layer 102 by way of suitable connection techniques. For example, the detector layer 102 can be coupled to the analog layer 104 by way of direct bonding, where indium bumps can be used to facilitate electrically connecting the analog layer 104 with the detector layer. Accordingly, the FPA 100 can include a high density bump interface 106, by way of which the detector layer 102 and the analog layer 104 are mechanically and electrically connected.

The FPA 100 additionally comprises a discrete digital signal processing (DSP) layer 108 that is mechanically and electrically (or optically) coupled to the analog layer 104. For example, the FPA 100 can comprise a (low density) via interface 110, where circuitry in the analog layer 104 can be electrically connected to circuitry in the DSP layer 108 by way of vias (e.g., through-silicon vias (TSVs)). As shown, the DSP layer 108 is positioned adjacent to the analog layer 104, such that the analog layer 104 is between the detector layer 102 and the DSP layer 108 in a three-dimensional stack.

The DSP layer 108 can include digital circuitry that is configured to receive the processed signal from the analog layer 104 and output digital data based upon the processed signal. Thus, the DSP layer 108 can include an application specific integrated circuit (ASIC) that is configured to perform desired digital processing function(s). Further, the DSP layer 108 can include one or more processing units, such as a field programmable gate array (FPGA).

The FPA 100 also includes an interconnect layer 112 that is adjacent to the DSP layer 108. For example, the FPA 100 can include a (low density) pad interface 114, which can be used to mechanically and electrically (or optically) bond the DSP layer 108 with the interconnect layer 112. The interconnect layer 112 can comprise conductive lines that are configured to receive digital data output by the DSP layer 108 and transmit the data output by the DSP layer 108 to an external processing unit. The processing unit can receive the digital data and, for instance, construct an image based upon the digital data. The interconnect layer 112 can be formed in a base silicon substrate 116 upon which the remainder of the stack is mounted.

While the analog layer 104 and the DSP layer 108 have been described above as outputting single signals, it is to be understood that, in operation, the analog layer 104 can output numerous (e.g., thousands, millions, etc.) of processed signals. Likewise, the DSP layer 108 can have several outputs, such that numerous digital signals from the DSP layer 108 (e.g., one per pixel) can be passed to an external processing unit by way of the interconnect layer 112.

While the FPA 100 shown in FIG. 1 has been described as including certain layers, it is to be understood that the FPA 100 is not limited to such layers, and that the FPA 100 may include any suitable layers that are configured to perform discrete functions (e.g., as needed for a particular mission). For example, exemplary circuitry that may be included in discrete layers in an FPA include, but are not limited to, A/D converters, readout electronics, processors, FPGA fabric, memory (e.g., DRAM, SRAM, flash), microelectronic mechanical system (MEMS) circuitry, fiber optic communications circuitry, additional sensors (multi-sensor), first order noise reduction circuitry, first order cluster reduction circuitry, etc.

The stacked-layer approach described herein has numerous advantages over conventional FPAs. For example, once discrete functional layers have been designed, a designer can utilize such functional layers for different designs to meet other remote-sensing mission needs while dramatically reducing development costs. That is, one would only pay to develop a functional layer once, and such functional layer can be reused for other missions. Accordingly, new technology can be incorporated as it is developed and other functional layers can be added over time. Therefore, a library of functional layers can be available for reuse by future remote-sensing mission applications.

The layers 102, 104, 108, and 112 can be interconnected in any suitable fashion. For instance, optical interconnections between layers may allow for high-speed data transfer. Further, magnetic sensors may be incorporated into layers, thus allowing for both electrical and optical signals for actuating different kinds of sensors (thus, enhancing overall system-level performance). Interfaces between layers can be well-characterized for noise resistance, signal loss, etc.

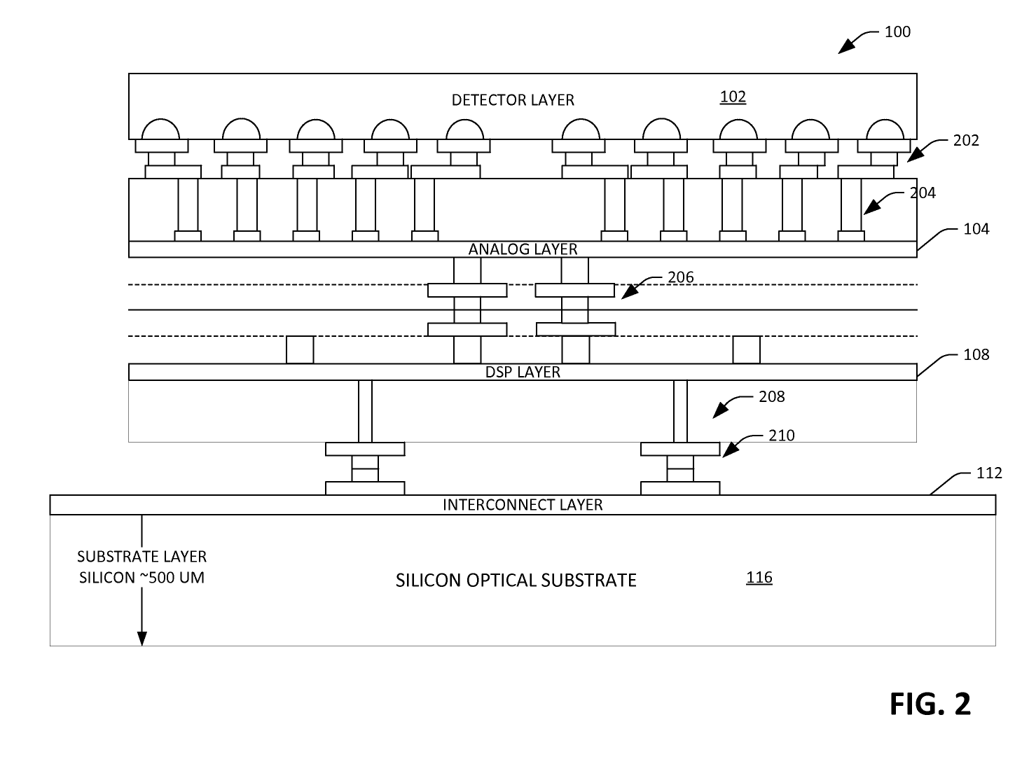

FIG. 2 is another cross-sectional view of the exemplary FPA 100. The cross-sectional view of the FPA 100 shown in FIG. 2 is presented to illustrate exemplary mechanisms for electrically connecting the detector layer 102, the analog layer 104, the DSP layer 108, and the interconnect layer 112 in the three-dimensional stack. The FPA 100 comprises a plurality of direct bond interconnects 202, which are relatively densely distributed. The direct bond interconnects 202 can at least partially form the high density bump interface 106 (FIG. 1).

The FPA 100 can further include a plurality of TSVs 204, which extend from the direct bond interconnects, respectively, through silicon of the analog layer 104. The FPA 100 can also include a second plurality of direct bond interconnects 206, which electrically and mechanically couple the analog layer 104 and the DSP layer 108. The FPA 100 also includes a plurality of TSVs 208 that extend from circuit elements of the DSP layer 108 through a silicon substrate of the DSP layer 108. The FPA also comprises a plurality of direct bond interconnects 210, where conductive lines that extend through the TSVs are coupled to the direct bond interconnects 210, and the direct bond interconnects 210 are also coupled to conductive lines of the interconnect layer 112.

The electrical performance of the direct bond interconnects 202, 206, and 210 and conductive lines that extend through the TSVs 204 and 208 may be well-characterized prior to the formation of the FPA 100. Accordingly, characteristics of these connecting elements can be taken into consideration in the overall stacking design. Alignment and tolerances corresponding to alignment can be provided as the process definition for the 3-D integration process, thus allowing the designer to address any critical performance-limiting factors. The alignment, for example, may be different for wafer-to-wafer attachment versus die-to-wafer attachment steps (e.g., when a tiled approach, as set forth below, is utilized).

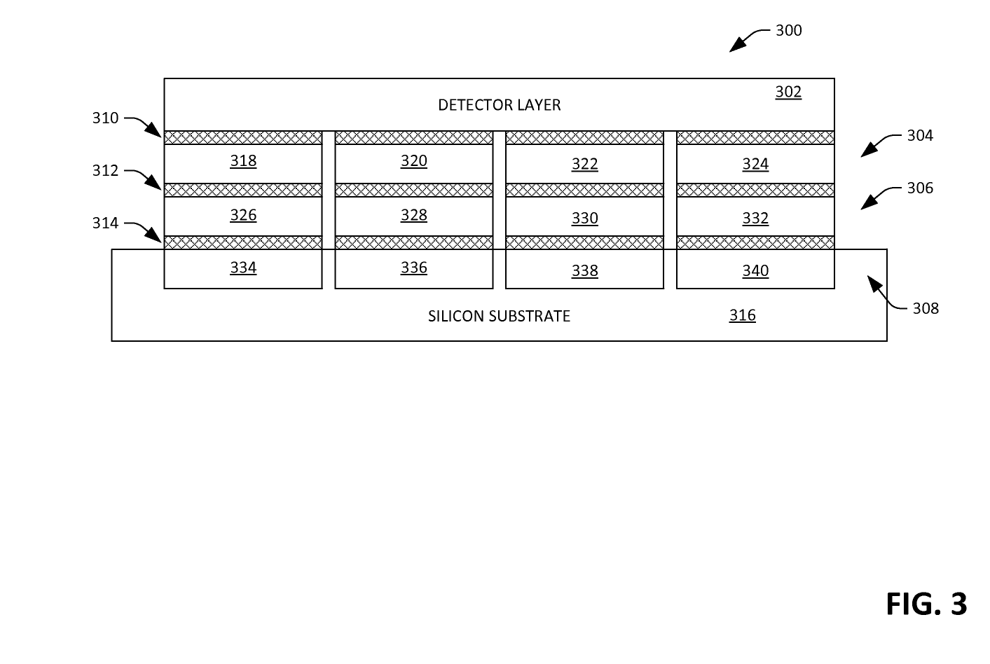

Now referring to FIG. 3, a cross-sectional view of another exemplary FPA 300 is illustrated. The FPA 300, like the FPA 100 set forth in FIGS. 1 and 2, comprises a plurality of layers: a detector layer 302 formed of a photodiode material, an analog layer 304 that comprises analog circuitry, a DSP layer 306 that comprises DSP circuitry, and an interconnect layer 308. The layers 302-308 are stacked one on top of another, and coupled by way of respective interfaces 310, 312, and 314. The interconnect layer 308 can be formed in a base silicon substrate 316.

In the exemplary FPA 300, however, the layers 304-308 each include a respective plurality of tiles. With more particularity, the analog layer 304 includes a plurality of identical analog tiles 318-324. Accordingly, each of the analog tiles 318-324 is configured to perform identical functionality. In an exemplary embodiment, each of the tiles 318-324 can correspond to a respective pixel, such that size of the tiles 318-324 can be a function of wavelength of radiation that is to be analyzed by the FPA 300. As can be ascertained, each of the identical analog tiles 318-324 is respectively electrically coupled to the detector layer 302. Thus, each of the tiles 318-324 can be configured to receive at least one signal from the detector layer 302, perform analog processing over such signal, and output at least one processed signal. As noted above, such processed signal may be a digital signal.

The DSP layer 306 comprises a plurality of identical DSP tiles 326-332. The plurality of DSP tiles 326-332 can be configured to perform identical functions with respect to received (processed) signals. In the example shown in FIG. 3, each DSP tile in the plurality of DSP tiles 326-332 receives a processed signal output by a respective analog tile in the plurality of analog tiles 318-324 (e.g., there is a one-to-one mapping between analog tiles and digital tiles). The FPA 300, however, may include more analog tiles than DSP tiles. Additionally or alternatively, the FPA 300 may include more DSP tiles than analog tiles. In a non-limiting example, a single DSP tile can be configured to receive processed signals from multiple analog tiles. Similarly, multiple DSP tiles can be configured to receive a single processed signal output by an analog tile (e.g., by way of multiplexing).

The FPA 300 also includes a plurality of identical interconnect tiles 334-340. Each interconnect tile 334-340 can be configured to perform identical functionality with respect to digital signals output by the DSP tiles 326-332. While the exemplary FPA 300 is shown as including an equal number of interconnect tiles to DSP tiles and analog tiles 318-324, it is to be understood that there may be more interconnect tiles 334-340 than either analog tiles or DSP tiles, or there may be less interconnect tiles than analog tiles or DSP tiles.

In operation, the detector layer 302 has radiation incident thereon, and the detector layer 302 generates electrical signals based upon the magnitude of the radiation and the angle of incidence of the radiation on the detector layer 302. The detector layer 302 is electrically coupled to the analog layer 304 at a plurality of positions in the detector layer 302. In an example, the spatial distribution of where the detector layer 302 is contacted can define pixel size, with each contact point corresponding to a respective pixel.

The analog layer 304 receives analog signals generated in the detector layer 302 and received from the detector layer 302. The analog layer 304, responsive to receiving the analog signals, performs analog processing thereover according to the function of the analog layer. As the analog layer 304 comprises a plurality of analog tiles 318-324, the analog layer 304 outputs a plurality of processed signals (e.g., at least one processed signal is output by each analog tile in the tiles 318-324).

The DSP tiles 326-332 in the DSP layer 306 receive processed signals output from the analog tiles 318-324 in the analog layer 304. The DSP tiles 326-332 perform identical digital processing function over the received processed signals to output digital signals. The digital signals are received by the interconnect tiles 334-340, which are configured to transmit the digital signals, for instance, to an external processing unit (e.g., CPU). The external processing unit can then be configured to construct an image, for example, based upon the data received by way of the interconnect tiles 334-340.

Composing processing layers from multiple identical tiles can be referred to as “tiling”, which is a mechanism where replicated functionality can be broken into smaller independent die (tile) and then connected together to perform a larger function (layer). For example, if a tile that supports an 8,000×8,000 pixel array is constructed, 16 of such tiles can be assembled together to support an FPA with approximately 1 billion pixels. An advantage to the tiling approach described herein is increase in manufacturability of a large area format FPA. More specifically, smaller die leads to higher yield, thus, the ability to tile smaller die to form larger devices, in turn, allows yet larger devices to be developed and manufactured (e.g., at higher yield).

To demonstrate this yield improvement, the relative yields of die that have similar or the same functionality, but where one die is much larger than the other die, can be estimated. The yield equation for a single monolithic die is relatively straightforward, where yield can typically be estimated from a technology/lithography yield curve. The yield for a device that is constructed on many die is more complex. The yield formulas set forth below address the expected yield of an FPA utilizing the wafer stacking and tiling assembly technologies described above.

Yield=(Detector Bond Yield)*(Stack Yield)*(Motherboard Assm. Yield)

where

(Motherboard Assm. Yield)=(Stack Mounting yield)^{(number of stacks)}

and

(Stack Yield)∝(Wafer/wafer bond yield)*(Pixel Die Yield)*(DPS Die yield)

The following example illustrates exemplary improvement in yield that may be acquired through utilization of the tiling referenced above:

### Assumptions:

1 cm×1 cm die yield=90%

5 cm×5 cm die yield=7%

Detector Bond Yield=95%

Stack Mounting Yield=95%

Wafer/Wafer Bond Yield=95%

Yield of Layer Made Up of One 5 cm×5 cm Device

$$\begin{matrix}Yield = ( Detector Bond Yield ) * ( 5 cm \times 5 cm Die Yield ) \\ = 0.95 * 0.07 \\ = 6.6 \%\end{matrix}$$

Yield of Layer Made Up of Twenty-Five 1 cm×1 cm Die Stacks

$$\begin{matrix}Yield = \{ ( Detector Bond Yield ) * ( 1 cm \times 1 cm Stack Yield ) * \\ ( Motherboard Assm Yield ) \} \\ = \{ ( Detector Bond Yield ) * \\ [ ( Wafer \text{/} Wafer Bond Yield ) * ( Pixel Die Yield ) * \\ ( DSP Die Yield ) ] * \\ [ {( Stack Mounting Yield )}^{( number of Stacks )} ] \} \\ = \{ 0.95 * [ 0.95 * 0.90 * 0.90 ] * [ 0.95 {*}^{25} ] \} \\ = \{ 0.95 * [ 0.77 ] * [ 0.28 ] \} \\ = 20.3 \%\end{matrix}$$

Tiling can also enable multi-mission reuse of tiles if missions need similar FPA functionality but require an array of different size. This technology may also eliminate the artificial size limitation of how big FPAs can be constructed. Larger FPAs often equate to a larger mission field of view.

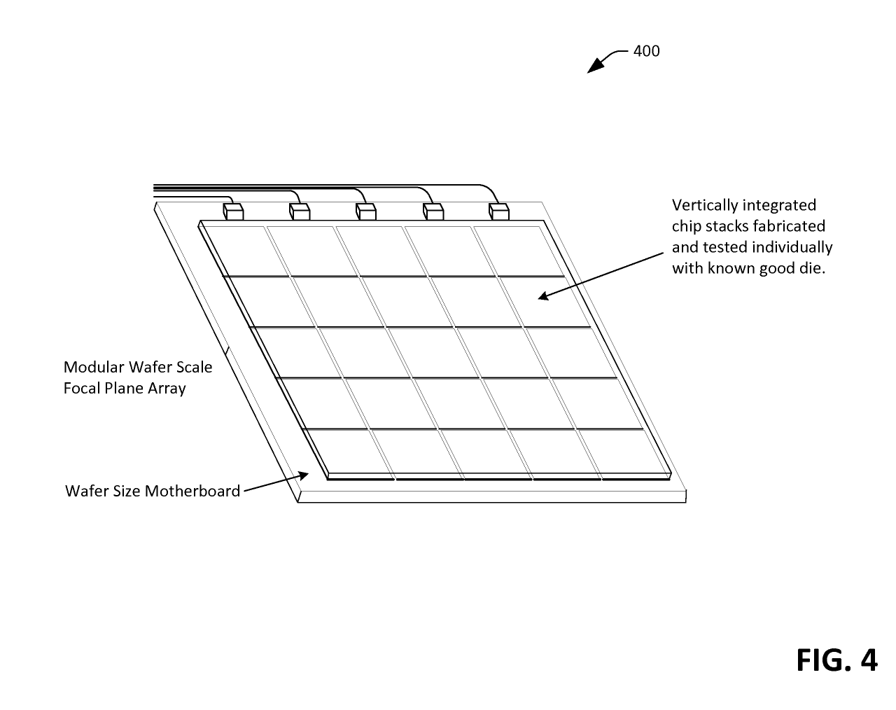

Now referring to FIG. 4, an isometric view of an exemplary FPA 400 is depicted. The FPA 400 is shown as including 25 vertically integrated chip stacks. When constructing the FPA 400, each tile can be individually tested with a known (gold standard) die. During testing, defective tiles can be discarded, while those meeting operational standards are retained. Combinations of tiles meeting operational standards may then also be tested, where defective combinations can be discarded, while combinations that meet operational standards can be retained. This process can continue until a layer that meets operational standards is constructed (e.g., where the layer has a size based upon a number of tiles therein). These layers may then be stacked with other known and tested layers, and the layers in combination can again be tested to ensure that operational standards are met.

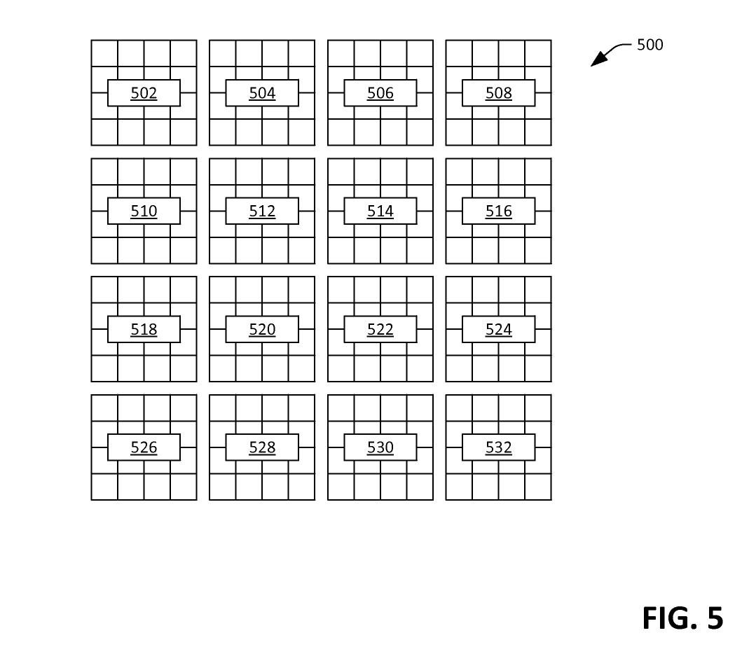

With reference now to FIG. 5, an overhead view of an exemplary processing layer of an FPA 500 is illustrated. The exemplary processing layer comprises 16 identical tiles 502-532. In an example, each of the tiles 502-532 may be made up of identical sub-tiles. As shown in FIG. 5, for example, each tile may be made up of 16 identical sub-tiles. The sub-tiles can have a size that corresponds to a smallest pixel size for an FPA. Combining sub-tiles, then, allows pixel size to be adjusted to the appropriate pixel size for each mission and for different types of detectors, such as very near infrared (VNIR), short wave infrared (SWIR), medium wave infrared (MWIR), and long wave infrared (LWIR). In a non-limiting example, each sub-tile may support a pixel size of about 0.55 μm×0.55 p.m. By selectively connecting sub-tiles, the pixel size can grow as a multiple of the base size to form pixels of other sizes. For example, a 2×2 array of the sub-tiles can result in formation of a tile that supports a pixel size of 1.1×1.1 p.m. Similarly, in the example shown in FIG. 5, a 4×4 array of sub-tiles, when connected, can support a 4.4×4.4 μm pixel size. To aggregate sub-tiles, capacitance of a sub-tile can be added together in the analog domain or digital domain to acquire total capacitance associated with a larger pixel.

Aspects described herein also facilitate automatic adjustment of a scan rate. Automatic adjustment of scan rate is a mechanism to adjust scan rate over a set of pixels based upon background conditions, such that an entire dynamic range is captured. When there is a high luminous background (e.g., during the day), the scan rate can be increased to ensure that integration well capacity used to capture photons does not saturate. The higher scan rate can result in a large dynamic range, as all of the light is captured. When there is low luminous background (e.g., at night), the scan rate can be decreased, because the well capacitor will not fill up as fast. This reduces the number of times the integration well capacitor is read, and thus, reduces noise induced by a read. Lower scan rate results in reduced noise levels, which in turn results in a larger dynamic range.

Accordingly, an FPA (e.g., the FPA 100 or 300) can include a circuit that monitors the luminous background for a set of pixels and scan rate can be set automatically by such circuit. By ensuring that there is never saturation (all the light is captured by reading often enough), but only read when needed (such that the number of reads is reduced to reduce noise induced by reads), dynamic range of the FPA can beam enhanced. It is also to be noted that automatically changing the scan rate is not identical to automatically changing integration time. The purpose of changing the scan rate is to ensure a well does not reach saturation, but on average, the pixels being serviced are one half full. Scaling integration time would throw away light that is undesirable.

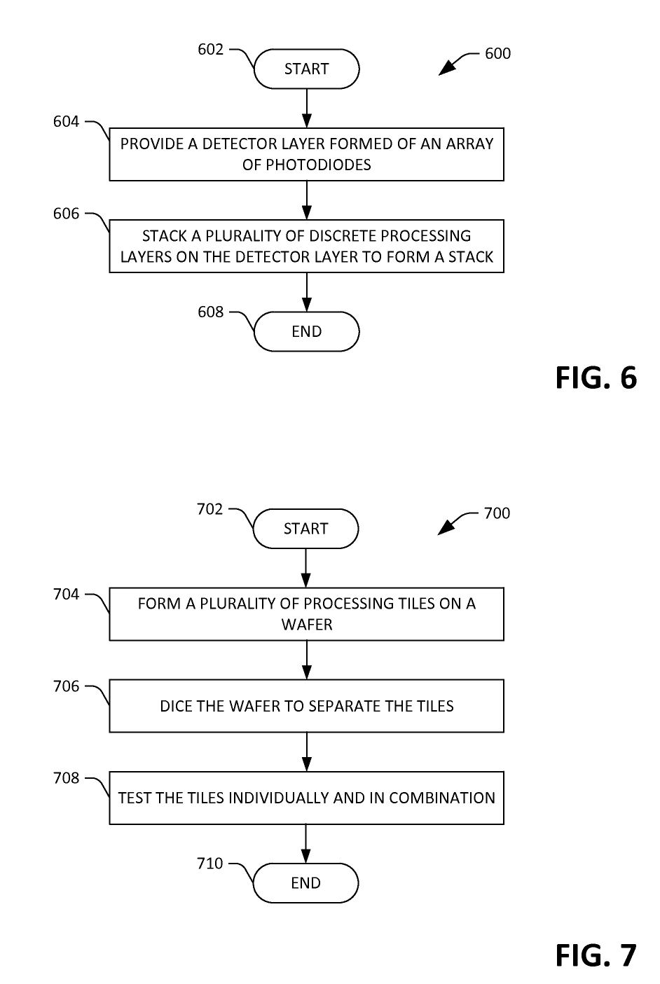

FIGS. 6-7 illustrate exemplary methodologies relating to developing and manufacturing an FPA. While the methodologies are shown and described as being a series of acts that are performed in a sequence, it is to be understood and appreciated that the methodologies are not limited by the order of the sequence. For example, some acts can occur in a different order than what is described herein. In addition, an act can occur concurrently with another act. Further, in some instances, not all acts may be required to implement a methodology described herein.

Turning now to FIG. 6, an exemplary methodology 600 that facilitates forming an FPA is illustrated. The methodology 600 starts at 602, and at 604 a detector layer is provided, wherein the detector layer is formed of an array of photodiodes. The photodiode array can be selected as a function of wavelength of radiation that is to be subject to analysis.

At 606, a plurality of discrete processing layers are stacked, one on top of another, to form a stack of discrete processing layers. Each discrete processing layer in the stack, as described above, can be formed separately and can be mechanically and electrically (or optically) coupled to at least one other discrete processing layer in the stack of discrete processing layers.

Now referring to FIG. 7, an exemplary methodology 700 that facilitates forming and testing a discrete processing layer that is to be included in an FPA is illustrated. The methodology 700 starts at 702, and at 704 a plurality of processing tiles are formed on a wafer using conventional semiconductor processing techniques. At 706, the wafer is diced to separate the tiles. Acts 704 and 706 can be repeated to acquire and test multiple die (tiles). At 708, the tiles are tested individually and then in combination. The methodology 700 completes at 710.

All patents, patent applications, publications, technical and/or scholarly articles, and other references cited or referred to herein are in their entirety incorporated herein by reference to the extent allowed by law. The discussion of those references is intended merely to summarize the assertions made therein. No admission is made that any such patents, patent applications, publications or references, or any portion thereof, are relevant, material, or prior art. The right to challenge the accuracy and pertinence of any assertion of such patents, patent applications, publications, and other references as relevant, material, or prior art is specifically reserved.

In the description above, for the purposes of explanation, numerous specific details have been set forth in order to provide a thorough understanding of the embodiments. It will be apparent however, to one skilled in the art, that one or more other embodiments may be practiced without some of these specific details. The particular embodiments described are not provided to limit the invention but to illustrate it. The scope of the invention is not to be determined by the specific examples provided above but only by the claims below. In other instances, well-known structures, devices, and operations have been shown in block diagram form or without detail in order to avoid obscuring the understanding of the description. Where considered appropriate, reference numerals or terminal portions of reference numerals have been repeated among the figures to indicate corresponding or analogous elements, which may optionally have similar characteristics.

It should also be appreciated that reference throughout this specification to “one embodiment”, “an embodiment”, “one or more embodiments”, or “different embodiments”, for example, means that a particular feature may be included in the practice of the invention. Similarly, it should be appreciated that in the description various features are sometimes grouped together in a single embodiment, figure, or description thereof for the purpose of streamlining the disclosure and aiding in the understanding of various inventive aspects. This method of disclosure, however, is not to be interpreted as reflecting an intention that the invention requires more features than are expressly recited in each claim. Rather, as the following claims reflect, inventive aspects may lie in less than all features of a single disclosed embodiment. Thus, the claims following the Detailed Description are hereby expressly incorporated into this Detailed Description, with each claim standing on its own as a separate embodiment of the invention.

What is claimed is:

1. A focal plane array (FPA) comprising:
a detector layer formed of a photodiode material;
a discrete analog layer that is adjacent to the detector layer and electrically coupled to the detector layer, the discrete analog layer comprises analog circuitry that is configured to receive an analog signal from the detector layer and output a processed signal that is based upon the analog signal; and
a discrete digital signal processing (DSP) layer that is adjacent to the discrete analog layer and electrically coupled to the discrete analog layer, the discrete analog layer positioned between the detector layer and the discrete DSP layer, the discrete DSP layer comprises digital circuitry that is configured to receive the processed signal from the discrete analog layer and output a digital signal based upon the processed signal.

2. The FPA of claim 1, the analog circuitry comprises an analog-to-digital (A/D) converter, the processed signal being digital.

3. The FPA of claim 1, further comprising an interconnect layer that is adjacent to the discrete DSP layer and electrically coupled to the discrete DSP layer, the discrete DSP layer positioned between the discrete analog layer and the interconnect layer, the interconnect layer comprises a conductive line that is configured to transmit the digital signal output by the discrete DSP layer to a processing unit.

4. The FPA of claim 1, the photodiode material being one of mercury cadmium telluride (HgCdTe), indium antimonide (InSb), indium gallium arsenide (InGaAs), or vanadium oxide (VOx).

5. The FPA of claim 1, the discrete analog layer comprises a plurality of identical analog tiles, each analog tile electrically coupled to a respective portion of the detector layer, the plurality of analog tiles configured to output a respective plurality of processed signals.

6. The FPA of claim 5, each analog tile comprises an A/D converter, the plurality of processed signals being digital signals output by the A/D converters of the analog tiles.

7. The FPA of claim 5, the discrete DSP layer comprises a plurality of identical DSP tiles that are respectively electrically connected to the plurality of analog tiles, each DSP tile in the plurality of DSP tiles configured to receive at least one processed signal from at least one analog tile in the plurality of analog tiles, each DSP tile configured to output a respective digital signal based upon the at least one processed signal.

8. The FPA of claim 7, each analog tile in the analog tiles comprises a plurality of electrically connected identical analog sub-tiles, and each DSP tile in the DSP tiles comprises a plurality of electrically connected identical DSP sub-tiles.

9. The FPA of claim 8, wherein a number of analog sub-tiles in each analog tile is a function of a wavelength of photons to be analyzed by the FPA.

10. The FPA of claim 1, the discrete DSP layer comprises a field programmable gate array (FPGA).

11. A method for forming a focal plane array (FPA) comprising:
providing a detector layer formed of a photodiode material; and
stacking a plurality of discrete processing layers to form a stack, wherein the stacking comprises communicatively contacting adjacent layers in the stack; and
electrically and mechanically coupling the stack with the detector layer.

12. The method of claim 11, further comprising:
forming each layer in the plurality of discrete processing layers, wherein at least one layer in the plurality of discrete processing layers is formed using a design in a library of designs.

13. The method of claim 12, wherein forming each layer in the plurality of layers comprises, for each layer, planarly arranging a plurality of identical tiles.

14. The method of claim 13, wherein forming each layer in the plurality of layers comprises forming each tile in the plurality of identical tiles, wherein forming each tile in the plurality of identical tiles comprises electrically connecting a respective plurality of identical sub-tiles to form a tile.

15. The method of claim 11, wherein the plurality of discrete processing layers comprises an analog processing layer that comprises analog circuitry, and wherein electrically and mechanically coupling the stack with the detector layer comprises electrically and mechanically coupling the analog processing layer with the detector layer.

16. The method of claim 15, wherein the plurality of discrete processing layers comprises a digital processing layer that comprises digital circuitry, and wherein stacking the plurality of discrete processing layers on the detector layer to form the stack comprises electrically and mechanically contacting the digital processing layer with the analog processing layer.

17. A focal plane array (FPA) comprising:
a detector layer formed of a photodiode material; and
a stack of discrete processing layers that are mechanically and electrically coupled to the detector layer, each discrete processing layer formed separately and mechanically and electrically bonded to at least one other discrete processing layer in the stack of discrete processing layers.

18. The FPA of claim 17, the stack of discrete processing layers comprises an interconnect layer that is configured to direct data to a processing unit, the processing unit configured to generate an image based upon the data received from the interconnect layer.

19. The FPA of claim 18, the interconnect layer comprises a plurality of conductive leads that output data that is indicative of intensity values of pixels in the image.

20. The FPA of claim 17, the photodiode material being one of mercury cadmium telluride (HgCdTe), indium antimonide (InSb), indium gallium arsenide (InGaAs), or vanadium oxide (VOx).
